(19) United States
(12) Patent Application Publication
(10) Pub. No.: US 2008/0054355 A1
(43) Pub. Date: Mar. 6, 2008

(54) Semiconductor device and method of manufacturing the same

(75) Inventor: Duck Ki Jang, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/896,039

(22) Filed: Aug. 29, 2007

(30) Foreign Application Priority Data
Aug. 29, 2006 (KR) 10-2006-0082429

(51) Int. Cl. H01L 29/94; H01L 21/336

(52) U.S. Cl. 257/343; 438/301; 257/E29.345; 257/E21.409

(57) ABSTRACT

A semiconductor device and a method for manufacturing the same are disclosed.

The embodiment improves a snapback breakdown voltage and preventing a phenomenon of dashed curves, by forming a gate to be overlapped with first and second drift regions and first and second regions formed in source and drain regions.

The present application claims priority under 35 U.S.C. 119 and 35 U.S.C. 365 to Korean Patent Application No. 10-2006-0082429 (filed on AUG. 29, 2006), which is hereby incorporated by reference in its entirety.

### TECHNICAL FIELD

The embodiment relates to a semiconductor device, and more particularly to a semiconductor device and a method of manufacturing the same capable of improving a snapback breakdown voltage and preventing a phenomenon of dashed curves.

### BACKGROUND

### Description of the Related Art

As the improvement of integration degree of a semiconductor device and the design technique in accordance thereof have been developed, the attempt to implement systems into one semiconductor chip has been progressed. Such one-chip of systems has mainly been developed as a technique integrating a controller, a memory, and other circuits operating in a low voltage, which are the main function of a system, into one-chip.

However, in order to more lighten and miniaturize the system, circuits having the main functions of an input terminal and an output terminal controlling a power supply of the system should be integrated into one-chip. The technique, which makes it possible, is a system on chip technique integrating a high voltage transistor and a low voltage CMOS transistor into one-chip.

Generally, the high voltage transistor comprises a gate, a channel formed in the lower of the gate, and a high-concentration N-type source region and high-concentration N-type drain region formed on both sides of the channel, and a low-concentration N-type drift region remaining a predetermined distance with the boundary line of the N-type drain region and surrounding it in order to disperse the electric field applied to the high-concentration N-type drain region when driving a device.

Meanwhile, in order to secure the high voltage breakdown voltage, a lateral diffused MOS (LDMOS) transistor, wherein the high-concentration N-type drain is horizontally arranged and the low-concentration drift region remaining a predetermined distance therefrom and surrounding it is also horizontally arranged, has recently been studied.

The lateral diffused MOS transistor would generate a problem actually evaluating a device structure, which is set as a target. For example, when an initial junction breakdown is used at 23 V level, although it seems to have a sufficient margin as compared to 13.5V, which is an operation voltage, the snapback breakdown is about 15V in an actual evaluation and thus it falls far below the expected value of 23V. Therefore, since the proper snapback breakdown is 18V or more, it is actually evaluated as 15V, which is smaller than that.

Therefore, since a desired snapback breakdown voltage is not obtained, it causes a problem of a serious device defect.

Furthermore, it causes a problem that a phenomenon of dashed curves occurs, where ID current value is not saturated in a drain sweep but the value is continuously increased.

### SUMMARY OF THE INVENTION

The embodiment provides a semiconductor device and a method of manufacturing the same capable of improving a snapback breakdown voltage and preventing a phenomenon of dashed curves, by forming a gate to be overlapped with a drift region.

A semiconductor device according to the first embodiment in order to accomplish the above object comprises: first and second drift regions formed in a source and drain regions of a substrate; a gate on the substrate between the first and second drift regions; and first and second impurity regions formed in the first and second drift regions, wherein the gate is formed to be overlapped with the respective first and second drift regions by the first and second regions.

A method of manufacturing a semiconductor device according to the second embodiment comprises the steps of: forming first and second drift regions in a source and drain regions of a substrate; forming a gate on the substrate between the source and drain regions; and forming first and second impurity regions in the first and second drift regions, wherein the gate is formed to be overlapped with the respective first and second drift regions by the first and second regions.

### BRIEF DESCRIPTION OF THE DRAWINGS

FIG. 1 is a schematic view of a lateral diffused MOS transistor according to the embodiment.

FIGS. 2A to 2E are process views sequentially showing a process of manufacturing a lateral diffused MOS transistor.

FIG. 3 is a graph showing an ID current depending on a driving voltage of a lateral diffused MOS transistor.

### DETAILED DESCRIPTION OF THE EMBODIMENTS

Hereinafter, preferred embodiments will be described in detail with reference to the accompanying drawings.

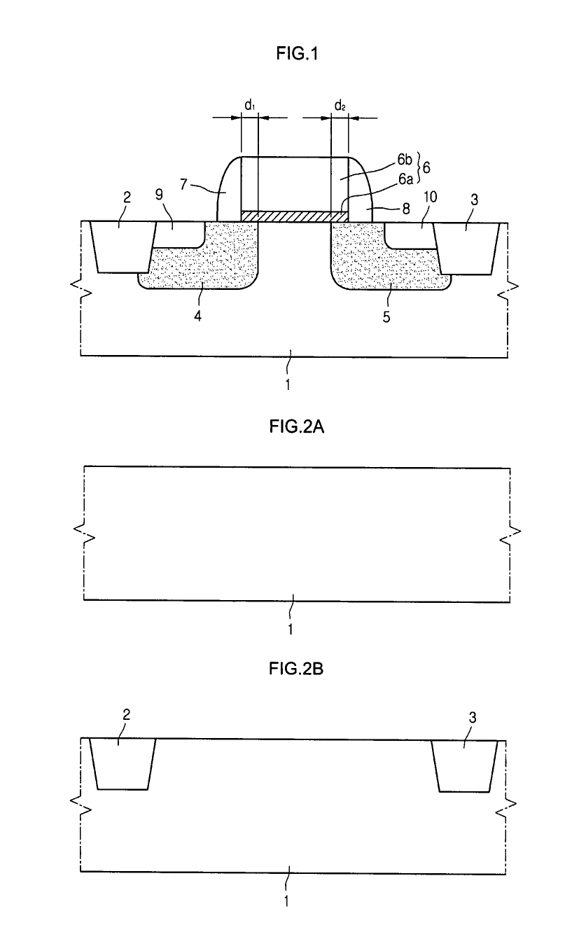

FIG. 1 is a schematic view of a lateral diffused MOS transistor according to the embodiment. For convenience of explanation, FIG. 1 shows a N-type MOS transistor.

As shown in FIG. 1, a low-concentration P type well region (not shown) is formed in the lower surface of a substrate 1, and a low-concentration first and second N-type drift regions 4 and 5 are formed in a source and drain regions thereon. The source and drain regions are formed to be spaced at a predetermined distance by means of a channel region therebetween. The first and second N-type drift regions 4 and 5 can be formed to be long in a horizontal direction.

High-concentration first and second N-type impurity regions 9 and 10 are formed within the first and second drift regions 4 and 5.

Isolation regions 2 and 3 are formed in order to isolate between neighboring devices.

A gate 6 comprising a gate insulating layer 6a formed of an oxide film and a gate conductor 6b formed of a polysilicon are formed on the substrate 1 between the source and drain regions. Of course, it is obvious that the gate conductor 6b is not limited to a polysilicon.

First and second spacers 7 and 8 are formed on the side of the gate 6.

The most important characteristics of the embodiment are to prevent the phenomenon of dashed curves by overlapping the gate 6 with respective first and second drift regions 4 and 5 by predetermined regions d1 and d2.

To this end, the width of the first and second drift regions 4 and 5 are formed not to be increased as compared to the related art but to be fixed. In other words, the width of the first and second drift regions 4 and 5 of the embodiment is the same as the width of the first and second drift regions of the related art. This is to prevent the size of the device from becoming large in the embodiment. In other words, in the embodiment, when the first and second drift regions 4 and 5 become large, the isolation regions 2 and 3 should be shifted towards left and right to be large accordingly. In this case, the interval between the isolation regions 2 and 3 dividing each device becomes large so that it causes a problem that the size of each device becomes large.

Therefore, in the embodiment, the first and second drift regions 4 and 5 are formed to have the same width as the related art.

To the contrary, the width of the gate 6 in the embodiment becomes larger as compared to the related art. In other words, since the gate 6 becomes large towards left and right, predetermined regions d1 and d2 are overlapped between the gate 6 and the first and second drift regions 4 and 5.

The predetermined regions d1 and d2 can be modified within the range of 0.1 to 0.4 μm, respectively. In other words, the first predetermined region d1 between the gate 6 and the first drift region 4 can be modified within the range of 0.1 to 0.4 μm, and the second predetermined region d2 between the gate 6 and the second drift region 5 can be modified within the range of 0.1 to 0.4 μm.

As described above, the gate 6 is formed to be overlapped with the first and second drift regions 4 and 5 by predetermined regions d1 and d2 by increasing the width of the gate 6, making it possible to prevent a phenomenon of dashed curves simultaneously with improving a snapback breakdown voltage.

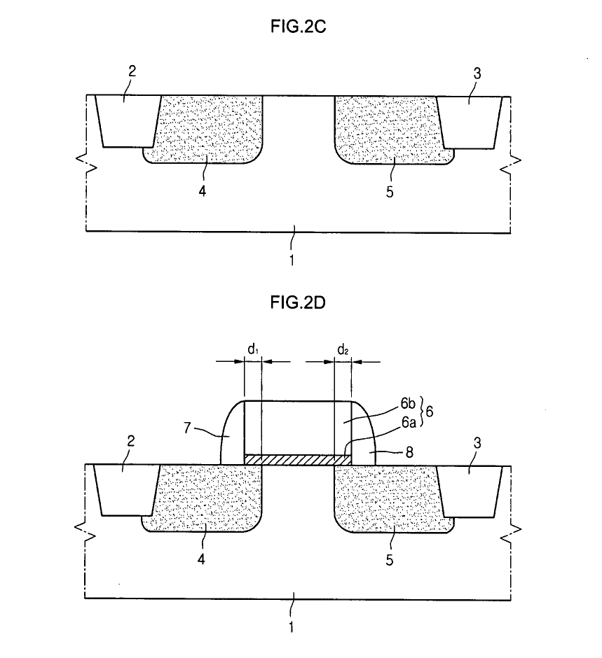

FIGS. 2A to 2E are process views sequentially showing a process of manufacturing a lateral diffused MOS transistor.

As shown in FIG. 2A, a P-type well region (not shown) is formed on the bottom of the substrate 1 by implanting low-concentration P-type impurity on the substrate 1 through an implant process and diffusing P-type impurity through a drive in process. Although not shown in FIG. 2A, neighboring device regions are implanted with N-type impurity so that an N-type well region (not shown) can be formed. Accordingly, the N-type well region or the P-type well for each device region can be formed.

As shown in FIG. 2B, isolation regions 2 and 3 can be formed at a predetermined interval for isolating between the devices. Such isolation regions 2 and 3 can be formed by ms of thermal oxidation manner. Herein, the interval may be a size for forming a unit lateral diffused MOS transistor.

As shown in FIG. 2C, first and second N-type drift regions 4 and 5 are formed by implanting low-concentration N-type impurity in source and drain regions on the substrate 1 having a P-type region through the implant process and diffusing it by the drive in process. The first and second N-type drift regions 4 and 5 can intensively be diffused in a horizontal direction by means of such diffusion. The MOS transistor having such a structure is a lateral diffused MOS transistor. The first and second N-type drift areas 4 and 5 can be formed to be long in a horizontal direction.

As shown in FIG. 2D, on the substrate 1 between the source and drain regions is formed a gate 6 and both sides thereof is formed with first and second spacers 7 and 8. The gate 6 can include a gate insulating layer 6a of an oxide film and a gate conductor 6b of a polysilicon

In this case, the gate 6 can be formed to be overlapped with the first and second drift regions 4 and 5 by predetermined regions d1 and d2.

To this end, the first and second drift regions 4 and 5 are fixed, while the width of the gate 6 is increased. As a result, the gate 6 is overlapped between the first and second drift regions 4 and 5.

The predetermined regions d1 and d2 each can be modified in the range of 0.1 to 0.4 μm. That is, the first predetermined region d1 between the gate 6 and the first drift region 4 can be modified in the range of 0.1 to 0.4 μm and the second predetermined region d2 between the gate 6 and the second drift region 5 can be modified in the range of 0.1 to 0.4 μm.

As above, due to the increase of the gate 6, it is overlapped with the first and second drift regions 4 and 5 by the predetermined regions d1 and d2 so that the phenomenon of dashed curves is prevented and at the same time, snap back breakdown voltage can be improved.

As shown in FIG. 2E, first and second N-type impurities 9 and 10 are formed within the first and second N-type drift regions 4 and 5 by implanting the high-concentration N-type impurity through the implant process using first and second spacers 7a and 7b as a mask.

The experiment is performed using the lateral diffused MOS transistor manufactured as above.

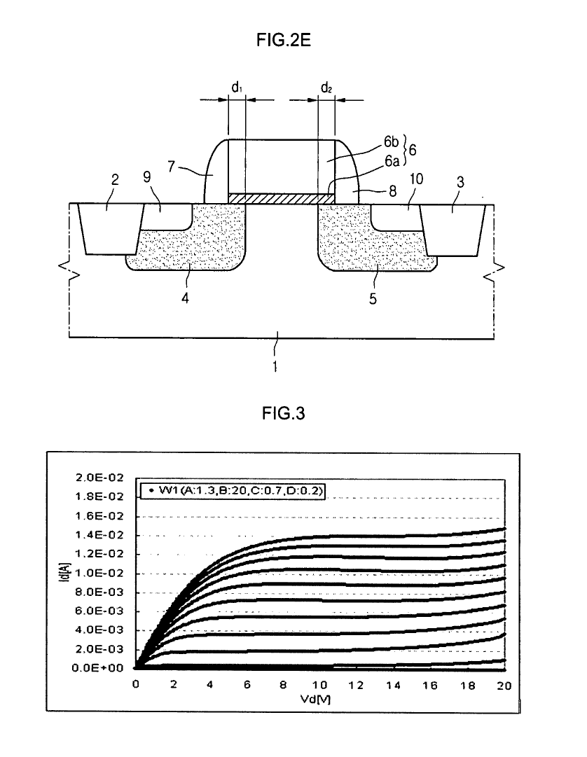

As shown in FIG. 3, the snap back breakdown voltage is not generated even in 20V.

The reason that the snap back breakdown voltage is improved is considered to be related to Max E-Field. That is, as the gate 6 is overlapped with the first and second drift regions 4 and 5 by a predetermined region, the gate conductor 6b serves as a conducting plate of the substrate 1 so that the Max E-Field is dispersed. As a result, higher snap back breakdown voltage can be maintained.

Also, it can be appreciated that driving voltage Vd is increased and at the same time, current ID is saturated. As the ID current is saturated, the ID current in the related art is not saturated but is continuously increased so that the phenomenon of the generated dashed curves can be prevented.

As described above, with the embodiment, the gate can be formed to be overlapped with the drift regions so that the snap back breakdown voltage is improved and the phenomenon of the dashed curves can be prevented.

Therefore, the device can stably be operated without malfunction so that the reliability of the device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
first and second drift regions formed in a source and drain regions of a substrate;
a gate on the substrate between the first and second drift regions; and
first and second impurity regions formed in the first and second drift regions,
wherein the gate is formed to be overlapped with the respective first and second drift regions by the first and second regions.

2. The semiconductor device according to claim 1, wherein the width of the respective drift regions are formed to be fixed and the width of the gate is formed to be increased in a horizontal direction.

3. The semiconductor device according to claim 2, wherein the bottoms of both sides of the gate are overlapped with some region of the upper surface of the respective drift regions.

4. The semiconductor device according to claim 2, wherein the first region has the range of 0.1 to 0.4 μm.

5. The semiconductor device according to claim 1, wherein the first region has the range of 0.1 to 0.4 μm.

6. A method of manufacturing a semiconductor device comprising the steps of:
forming first and second drift regions in a source and drain regions of a substrate;
forming a gate on the substrate between the source and drain regions; and forming first and second impurity regions in the first and second drift regions,
wherein the gate is formed to be overlapped with the respective first and second drift regions by the first and second regions.

7. The method according to claim 6, wherein the bottoms of both sides of the gate are overlapped with some region of the upper surface of the respective drift regions.

8. The method according to claim 6, wherein the first region has the range of 0.1 to 0.4 μm.

9. The method according to claim 6, wherein the first region has the range of 0.1 to 0.4 μm.
